(19) United States
(12) Patent Application Publication
(10) Pub. No.: US 2026/0089870 A1
(43) Pub. Date: Mar. 26, 2026

(54) BAFFLE FOR AN INFORMATION PROCESSING DEVICE

(71) Applicant: HEWLETT PACKARD ENTERPRISE DEVELOPMENT LP, Spring, TX (US)

(72) Inventors: Yu han Lin, Taipei (TW); Kueiching Hsu, Taipei (TW); Tung-chun Tsai, Taipei (TW)

(21) Appl. No.: 19/034,341

(22) Filed: Jan. 22, 2025

Related U.S. Application Data
(60) Provisional application No. 63/698,723, filed on Sep. 25, 2024.

(51) Int. Cl. H05K 7/20

(52) U.S. Cl. CPC H05K 7/20145; H05K 7/20727

(57) ABSTRACT

A baffle to restrain a flow of fluid to a fluid flow path defined in an information processing device is disclosed. The baffle includes a fixed end, a free end opposite to the fixed end, the attachment portion, and a finger portion. The attachment portion is at the fixed end and includes a mechanical mounting member. The mechanical mounting member is configured to detachably couple to a support structure of the information processing device so as to mount the attachment portion to the information processing device. The finger portion includes a plurality of flaps extending from the attachment portion to the free end and configured to restrain the flow of the fluid to the fluid flow path. The finger portion includes a compliant material such as one of a rubber material or a silicon material.

### BACKGROUND

An information processing device such as a computer, a networking device, or the like includes various electronic components such as primary system boards, processors, memory modules, resistors, capacitors, or the like to provide some functions. During the operation of such an information processing device, each of these electronic components may generate significant amounts of heat. If adequate amounts of heat generated by these electronic components are not removed from the information processing device, the heat may exceed thermal specifications of the electronic components, resulting in degraded performance, reliability, and life expectancy of the electronic components, and in some cases failure of such electronic components. Hence, the information processing device additionally includes fans to direct fluid over such electronic components so as to dissipate heat generated from the electronic components.

### BRIEF DESCRIPTION OF THE DRAWINGS

Various examples will be described below with reference to the following figures.

FIG. 1 includes a schematic view of a baffle according to an example of the present disclosure.

FIG. 2 includes a schematic view of an information processing device including one or more baffles of FIG. 1 according to the present disclosure.

FIG. 3 includes a perspective view of a first baffle according to an example of the present disclosure.

FIG. 4 includes a perspective view of a portion of an information processing device having the first baffle of FIG. 3 according to an example of the present disclosure.

FIG. 5 includes a perspective view of a second baffle according to an example of the present disclosure.

FIG. 6 includes a perspective view of another second baffle according to an example of the present disclosure.

FIG. 7 includes a perspective view of a third baffle according to an example of the present disclosure.

FIG. 8A includes a perspective view of a portion of another information processing device having the second baffles of FIGS. 5-6 and a third baffle of FIG. 7 according to an example of the present disclosure.

FIG. 8B includes an expanded perspective view of the second baffle detachably coupled to a memory support member of the information processing device of FIG. 8A according to an example of the present disclosure.

FIG. 8C includes an expanded perspective view of the other second baffle detachably coupled to another memory support member of the information processing device of FIG. 8A according to an example of the present disclosure.

FIG. 8D includes an expanded perspective view of the third baffle detachably coupled to a top cover holder of the information processing device of FIG. 8A according to an example of the present disclosure.

FIG. 9 includes a perspective view of yet another second baffle according to an example of the present disclosure.

FIG. 10 includes a perspective view of a portion of another information processing device having the other second baffle of FIG. 9 according to an example of the present disclosure.

FIG. 11 is a flowchart depicting a method of installing a baffle in an information processing device according to an example of the present disclosure.

### DETAILED DESCRIPTION

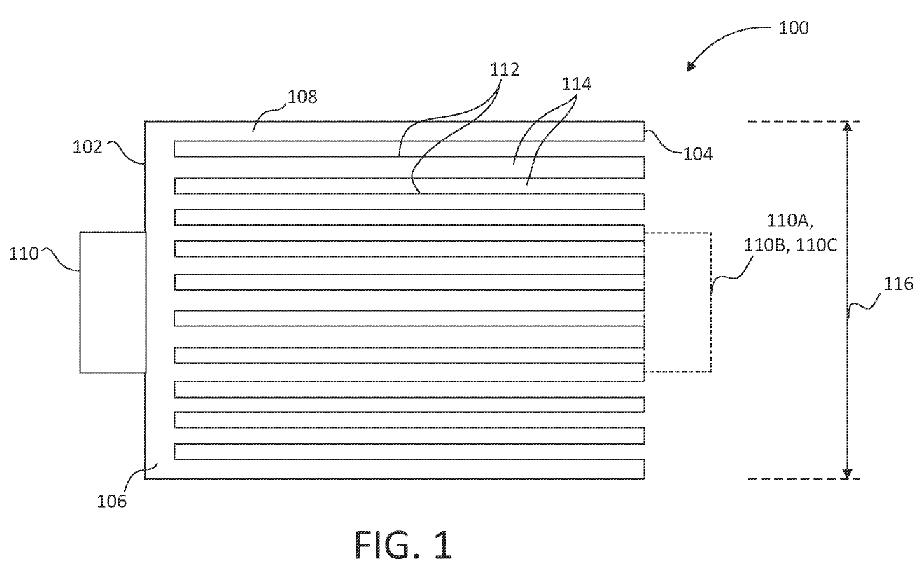

The following detailed description refers to the accompanying drawings. For purposes of explanation, certain examples are described with reference to the components illustrated in FIGS. 1-11. The functionality of the illustrated components may overlap, however, and may be present in a fewer or greater number of elements and components. Moreover, the disclosed examples may be implemented in various environments and are not limited to the illustrated examples. Wherever possible, the same reference numbers are used in the drawings and the following description to refer to the same or similar parts. It is to be expressly understood, however, that the drawings are for the purpose of illustration and description only. While several examples are described in this document, modifications, adaptations, and other implementations are possible. Accordingly, the following detailed description does not limit the disclosed examples. Instead, the proper scope of the examples disclosed may be defined by the appended claims.

An information processing device may include fans which are configured to direct fluid (e.g., air) over the electronic components, such as primary system boards, CPUs, GPUs, DIMMs, or the like of the information processing device to dissipate heat generated from such electronic components. In particular, fans may draw the fluid from a first external environment along a first direction into a chassis of the information processing device and direct the fluid towards a second external environment via a fluid flow path defined along the electronic components disposed in the chassis. However, some portions of the fluid directed from the fans may flow towards dead zones in the chassis (e.g., an area formed between the two adjacent fans) instead of flowing in the fluid flow path. Further, the fluid from the dead zones may tend to flow along a second direction opposite to the first direction towards the first external environment. Additionally, some portions of the fluid may tend to flow away from the fluid flow path. Since the fluid directed by the fans along the first direction is not optimally used to dissipate the heat, the thermal performance of the electronic components may be affected.

To address the aforementioned problems, the information processing device may include a baffle assembly configured to block the portion of the fluid that tends to flow towards the dead zones and further guide such portion of the fluid towards the fluid flow path, thereby allowing the fluid to optimally dissipate the heat generated by the electronic components before leaving the chassis to the second external environment. Generally, the baffle assembly includes a sponge made of a porous material and a holder made of a plastic material. In particular, the sponge is attached to the holder using adhesives to form the baffle assembly. The holder of the baffle assembly is later coupled to the chassis so as to releasably mount the baffle assembly to the information processing device. Since the sponge is fragile in nature, it may tend to wear out often due to the heat, vibrations, shocks in the information processing device, thereby necessitating frequent replacements of the sponge from the baffle assembly. The replacement of the sponge from the baffle assembly may be cumbersome, time-consuming, and expensive as it requires some special solutions to detach the sponge from the holder of the baffle assembly. An alternative solution may require the entire baffle assembly to be replaced instead of merely replacing the sponge from the baffle assembly. However, replacing the baffle assembly may be expensive and may further add to environment waste, and also depends on the availability of inventory of a new baffle assembly, and may even require shutting down of the information processing device. Furthermore, the worn section of the sponge may create debris, which may be deposited on the electronic components, thereby creating bad customer experience and even effecting the thermal performance of the electronic components and may even force them to replace some of the affected electronic components.

A technical solution to the aforementioned problems may include providing a baffle (or a unified baffle) made of compliant material and having an attachment portion and a finger portion extending from the attachment portion. The attachment portion may include mechanical mounting member configured to detachably couple the baffle to a pre-existing support structure of the information processing device and the finger portion may be configured to restrain a flow of fluid to a fluid flow path defined in the information processing device. In some examples, the compliant material may be a rubber material or a silicone material, which has heat resistance and flexibility characteristics that are greater than that of the sponge of the conventional baffle assembly. Hence, the baffle has a longer shelf-life than that of the sponge of the conventional baffle assembly. Further, the attachment portion is integrally formed with the finger portion to form the unitary baffle. Thus, the attachment portion having the mechanical mounting member may not be separately attached to the finger portion of the baffle using adhesive as in the case of the sponge, which is separated attached to a holder in the conventional baffle assembly. Further, the mechanical mounting member may be easily attached to and detached from the pre-existing support structure of the information processing device. Furthermore, the finger portion includes a plurality of flaps, which are separated from one another via a groove of a plurality of grooves. In such cases, each flap of the plurality of flaps may be independently movable, thus allowing any obstructing electronic element such as cable or wires of the information processing device to pass through the finger portion via a corresponding groove of the plurality of grooves. Additionally, the each of the plurality of flaps is independently bendable, thus allowing the finger portion to be disposed in a constrained space of the information processing device which is narrower than a width of the finger portion. In some examples, the mechanical mounting member may include a hook, a protrusion, or a groove, which may engage with a keyhole, a groove, or a hook, respectively, formed in the pre-existing support structure to detachably couple the baffle to the pre-existing support structure.

Since only the baffle may have to be replaced, whenever required, without the need to replace a separate holder as in the conventional baffle assembly, the replacement of the baffle is not cumbersome, expensive, and time-consuming. Furthermore, the baffle may be easily formed in multiple shapes based on its position for deployment in the information processing device. Further, since the baffle is made of a rubber or a silicone material, there is no environmental waste as it was with the usage of the holder made of plastic part in the conventional baffle assembly. Hence, the baffle is an eco-friendly baffle.

In the description hereinafter, example power input connector module and/or information processing device are described with the help of several views oriented per a first axis 1 extending along a horizontal direction, a second axis 2 extending along a lateral direction, and a third axis 3 extending along a vertical direction, which are marked in the respective Figures. Further, the vertical, axial, and lateral directions may be perpendicular to each other and the measurements along the vertical, axial, and lateral directions may be referred to as a height, a width, and a length, respectively. The axes 1, 2, and 3 and directions or positional relationships described herein in relation to these axes are fixed relative to the devices as shown in the figures and not to any external reference frame (such as the ground), and direction terms used herein should be understood in relation to these axes and not to any external reference frame. For example, horizontal and vertical, as used herein, do not refer to orientations relative to the ground.

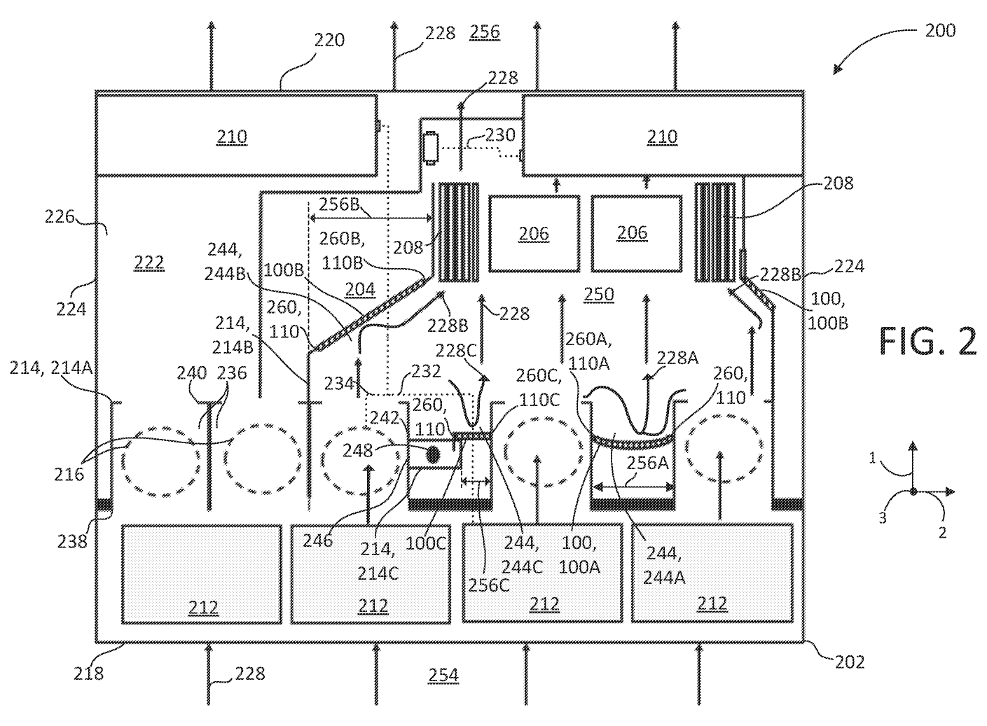

Referring to the Figures, FIG. 1 depicts a schematic view of a baffle 100 for an information processing device 200 (as shown in FIG. 2). In one or more examples, the baffle 100 may be used to restrain or regulate a flow of a fluid 228 (e.g., air, or liquid, as shown in FIG. 2) along a fluid flow path 250 (as shown in FIG. 2) defined in the information processing device 200. In some examples, the baffle 100 includes a fixed end 102, a free end 104, an attachment portion 106, and a finger portion 108.

The fixed end 102 is one of the end portions of the baffle 100 which may be configured to be attached to a support structure 214 (as shown in FIG. 2) of the information processing device 200. The free end 104 is another one of the end portions of the baffle 100 which may not be restrained or fixed in place. In other words, the free end 104 may be movable or bendable relative to the fixed end 102. In some examples, the free end 104 is opposite to the fixed end 102.

The attachment portion 106 may be a region of the baffle 100 which is located at the fixed end 102 of the baffle 100. The attachment portion 106 includes a mechanical mounting member 110 which may be configured to detachably couple with the support structure 214 of the information processing device 200 so as to releasably mount the attachment portion 106 to the information processing device 200. In certain examples, the attachment portion 106 may include at least one mechanical mounting member 110. In some other examples, the attachment portion 106 may include more than one mechanical mounting member 110, e.g., two mechanical mounting members. In some examples, the mechanical mounting member 110 may be a hook, a protrusion, or a groove, which may be configured to detachably couple with a complementary mechanical mounting member of the support structure 214 so as to releasably mount the baffle 100 to the information processing device 200.

The finger portion 108 may be another region of the baffle 100 which is located at the free end 104 of the baffle 100 and may be configured to restrain the flow of fluid 228 to the fluid flow path 250 defined in the information processing device 200. In some examples, the finger portion 108 includes a plurality of flaps 112, each extending from the attachment portion 106 to the free end 104. In particular, the plurality of flaps 112 is spaced apart from each other by a plurality of grooves 114 extending from the free end 104 towards the attachment portion 106. In some examples, each flap of the plurality of flaps 112 is independently movable so as to allow an obstructing electronic element (e.g., second cable 232) of the information processing device 200 to pass from one area to another area of the information processing device 200 by extending the second cable 232 via a corresponding groove 114 of the finger portion 108. Similarly, in some other examples, each flap 112 may be independently bendable to allow the finger portion 108 to be disposed in a constrained space of the information processing device 200 having a first width 256A (as shown in FIG. 2) which is narrower than a width 116 of the finger portion 108.

In some examples, the finger portion 108 includes a compliant material, such as a rubber material or a silicone material. In such examples, the attachment portion 106 may include a non-compliant material which may be coupled to the finger portion 108 to form the baffle 100. However, in some other examples, the attachment portion 106 may also include the compliant material. In such examples, the baffle 100 may be a unitary component made of either the rubber material or the silicone material. In some examples, the finger portion 108 may have one of a planar geometry or an angular geometry depending on the position of deployment of the baffle 100 in the information processing device 200. In one or more examples, the compliant material is a thermally non-conductive material, thus it may not transfer the heat to the support structure or any electronic components therein.

The baffle 100 may be deployed on the support structure 214 including one of a fan cage, a top cover holder of a chassis, a memory support member of the chassis, or the like. In such examples, the baffle 100 may restrain or regulate the flow of the fluid 228 along the fluid flow path 250 defined in the information processing device 200.

FIG. 2 depicts a schematic top view of an information processing device 200, such as a computer (e.g., a server, a storage device), a networking device (e.g., a switch, an access point), or the like. In the example of FIG. 2, the information processing device 200 is a computer. The information processing device 200 includes a baffle 100 of FIG. 1, a chassis 202, a primary system board 204, processors 206, memory modules 208, power supply units 210, storage modules 212, support structures 214, and fans 216.

As discussed herein in the example of FIG.1, the baffle 100 is made of a compliant material and is used to restrain or regulate a flow of a fluid 228 along a fluid flow path 250 defined in the information processing device 200. In some examples, the baffle 100 includes a first baffle 100A, a plurality of second baffles 100B, and a third baffle 100C. Similar to the baffle 100, each of the first, second, and third baffles 100A, 100B, 100C may be made of a compliant material and may include a fixed end 102, a free end 104, an attachment portion 106, and a finger portion 108. The attachment portion 106 is at the fixed end 102 and includes a mechanical mounting member 110 which is configured to detachably couple to a support structure 214 of the information processing device 200 so as to releasably mount the attachment portion 106 to the information processing device 200. Further, the finger portion 108 includes a plurality of flaps 112 extending from the attachment portion 106 to the free end 104 and is configured to restrain the flow of the fluid 228 to the fluid flow path 250 defined in the information processing device 200. It may be noted herein that the baffle 100 is not discussed in detail to maintain the brevity of the disclosure. The compliant material of each of the first, second, and third baffles 100A, 100B, 100C may include one of a rubber material or a silicone material.

The chassis 202 includes panels such as a front panel 218 and a rear panel 220, a base 222, a cover (not shown), and a pair of sidewalls 224. In one or more examples, the pair of sidewalls 224 is attached to the front and rear panels 218, 220 and the base 222 to define an enclosure 226 therein. The primary system board 204, the processors 206, the memory modules 208, the power supply units 210, the storage modules 212, the support structures 214, and the fans 216 are disposed in the enclosure 226. Further, each of the front panel 218 and the rear panel 220 may include openings (not shown) to allow the flow of the fluid 228 along a first axis 1 to pass through the enclosure 226 from one panel to another panel, e.g., from the front panel 218 to the rear panel 220.

The primary system board 204 such as a mother board is disposed on and coupled to the base 222 of the chassis 202. The primary system board 204 includes the processors 206, such as a central processing unit and/or a graphics processing unit, and memory modules 208 such as DIMMs. The primary system board 204 may include some electronic elements, such as resistors, capacitors, connectors, or the like mounted thereon, which are not discussed herein to maintain the brevity of the disclosure.

In some examples, the power supply units 210 may be disposed adjacent to the rear panel 220. Each of the power supply units 210 may be electrically connected to an external power source (not shown) to receive power. Further, each of the power supply units 210 may regulate the received power and supply the regulated power to electronic components of the information processing device 200. For example, the primary system board 204 is electrically connected to one of the power supply units 210 via a first cable 230 so as to receive the regulated power from one of the power supply units 210. In such examples, the primary system board 204 may further supply the received power to the processors 206, memory modules 208, and other electronic elements mounted thereon.

In some examples, the storage modules 212 may be disposed adjacent to each other along a second axis 2 of the chassis 202 and positioned adjacent to the front panel 218. Each storage module 212 is electrically connected to one of the power supply units 210 through a second cable 232 so as to receive the power from one of the power supply units 210.

In some examples, the fans 216 may be disposed adjacent to each other along the second axis 2 of the chassis 202 and positioned downstream of the storage modules 212 relative to the flow of the fluid 228 into the chassis 202. Further, each fan 216 is electrically connected to one of the power supply units 210 via a third cable 234. In some examples, the fans 216 are supported by the support structure 214 such as a fan cage 214A. The fan cage 214A includes a plurality of fan housings 236 configured to support a corresponding fan 216 therein. Further each fan housing 236 has a first opening 238 and a second opening 240 opposite to the first opening 238. In such examples, each fan 216 is configured to draw the fluid 228 into the fan housing 236 via the first opening 238 and direct the pumped fluid 228 out of the fan housing 236 via the second opening 240. In particular, the pumped fluid 228 is directed along the fluid flow path 250 defined along the processors 206, memory modules 208, the primary system board 204 of the information processing device 200.

In some examples, the support structure 214 may be configured to house and/or provide support to components such as processors 206, memory modules 208, fans 216, and cover of the information processing device 200. In certain examples, the support structure 214 is one of a fan cage 214A, memory support members 214B, a top cover holder, or the like. The support structure 214 may be coupled to the base 222 and/or the cover and may include one or more complementary mechanical mounting members 260 which are configured to detachably couple with a corresponding baffle 100 so as to releasably mount the baffle 100 to the information processing device 200.

In some examples, the fan cage 214A may be disposed downstream of the storage modules 212 relative to the flow of the fluid 228 into the chassis 202. The fan cage 214A is configured to house and provide support to the fans 216 disposed therein. The fan cage 214A may include one or more first complementary mechanical mounting members 260A configured to engage with corresponding one or more first mechanical mounting members 110A of the first baffle 100A so as to detachably couple the first baffle 100A to the fan cage 214A. In some other examples, the memory support members 214B may be disposed downstream of the fan cage 214A relative to the flow of the fluid 228 into the chassis 202 and are configured to partially enclose the processors 206 and the memory modules 208. Each of the memory support members 214B may include one or more second complementary mechanical mounting members 260B configured to engage with corresponding one or more second mechanical mounting members 110B of the second baffle 100B so as to detachably couple the second baffle 100B to the corresponding memory support member 214B. Similarly, in some examples, the top cover holder 214C is disposed between two adjacent fan housings 236 of the fan cage 214A such that at least one end wall 246 of the top cover holder 214C is coupled to one sidewall 242 of a fan housing 236. Further, the top cover holder 214C includes a pin 248 extending upwards along a third axis 3 and configured to engage with a recess of the cover to detachably couple and provide support to the cover of the information processing device 200. The top cover holder 214C may include one or more third complementary mechanical mounting members 260C configured to engage with corresponding one or more third mechanical mounting members 110C of the third baffle 100C so as to detachably couple the third baffle 100C to the top cover holder 214C.

In one or more examples, the fan cages 214A and/or the memory support members 214B are positioned such that some portions of the pumped fluid 228 may not effectively flow along the fluid flow path 250 and may rather flow into one or more dead zones 244 in the fluid flow path 250. In particular, in some examples, some of the fan cages 214A are disposed spaced apart from each other by a first width 256A along the second axis 2 and thereby creating a first dead zone 244A along the fluid flow path 250. In such examples, the first baffle 100A is detachably coupled to the fan cage 214A such that the first baffle 100A laterally covers the first dead zone 244A along the second axis 2. In some examples, the first baffle 100A may have a width 116 which is greater than the first width 256A (or gap) between the two adjacent fan cages 214A. In such examples, a finger portion of the first baffle 100A may be bent to allow the first baffle 100A to be disposed in the first width 256A.

In some examples, the memory support members 214B are offset from the memory modules 208 by a second width 256B along the second axis 2 and thereby creating a second dead zone 244B along the fluid flow path 250. In such examples, each baffle of the second baffles 100B is detachably coupled to a corresponding memory support member 214B such that the second baffle 100B angularly covers the second dead zone 244B.

In some other examples, some other fan cages 214A and the top cover holder 214C are disposed spaced apart from each other by the third width 256C along the second axis 2, and thereby creating a third dead zone 244C along the fluid flow path 250. In such examples, the third baffle 100C is detachably coupled to the top cover holder 214C such that the third baffle laterally covers the third dead zone 244C and does not allow the portion of the fluid 228 to flow into the third dead zone 244C. In some examples, each flap of the finger portion of the third baffle 100C is independently moved so as to allow an obstructing electronic element (e.g., the second cable 232) of the information processing device 200 to pass from a downstream area (relative to the flow of fluid 228) to the upstream area (relative to the flow of fluid 228) of the information processing device 200 by extending the second cable 232 via a groove 114 of the finger portion.

In one or more examples, the baffle 100 may be easily attached and/or removed from the existing support structures 214 of the information processing device 200 using the mechanical mounting member 110 and without the need for a separate holder for detachably coupling with the support structure 214. Thus, the baffle 100 of the present disclosure may be easily replaced, whenever required, without the need to replace a separate holder as in the case of a conventional baffle assembly. Accordingly, the replacement of the baffle 100 is not cumbersome, expensive, and time-consuming.

During operation of the information processing device 200, the fans 216 draws fluid 228 from a first external environment 254 into the chassis 202 via the openings formed in the front panel 218 of the chassis 202. The fluid 228 may be directed towards the first openings 238 of the fan cage 214A. Accordingly, each fan 216 may pump the fluid 228 available at its first opening 238 into the fluid flow path 250 via the second opening 240. However, a first portion 228A of the pumped fluid 228 may be directed towards the first dead zone 244A. In such examples, the first baffle 100A disposed at the first dead zone 244A may not allow the first portion 228A of the fluid 228 to flow into first dead zone 244A and guide the first portion 228A of the fluid 228 back into the fluid flow path 250. In other words, the first baffle 100A may direct the first portion 228A of the fluid 228 moving towards the first dead zone 244A to flow along the fluid flow path 250. Similarly, the second baffles 100B disposed at the second dead zones 244B may not allow a second portion 228B of the fluid 228 to flow into the second dead zone 244B and guide the second portion 228B of the fluid 228 back into the fluid flow path 250. In other words, the second baffles 100B may direct the second portion 228B of the fluid 228 moving towards the second dead zone 244B to flow along the fluid flow path 250. Furthermore, the third baffle 100C disposed at the third dead zone 244C may not allow a third portion 228C of the fluid 228 to flow into third dead zone 244C and guide the third portion 228C of the fluid 228 back into the fluid flow path 250. In other words, the third baffle 100C may direct the third portion 228C of the fluid 228 moving towards the third dead zone 244C to flow along the fluid flow path 250. The fluid 228 flowing in the fluid flow path 250 may flow over the electronic components such as the processors 206, memory modules 208, and primary system board 204, and later dissipate the heat away from such electronic components before exiting from the chassis 202 to a second external environment 256 via the openings formed in the rear panel 220 of the chassis 202.

Since the baffle 100 is made of compliant material such as rubber and silicone, they may have a longer service life in comparison with a sponge used in a conventional baffle assembly. Further, since the baffle 100 is made of the compliant material, there is no environmental waste as it was with the usage of a holder made of plastic material in the conventional baffle assembly. Hence, the baffle 100 is an eco-friendly baffle. Furthermore, the baffle 100 may be easily formed in multiple shapes based on its position for deployment in the information processing device 200.

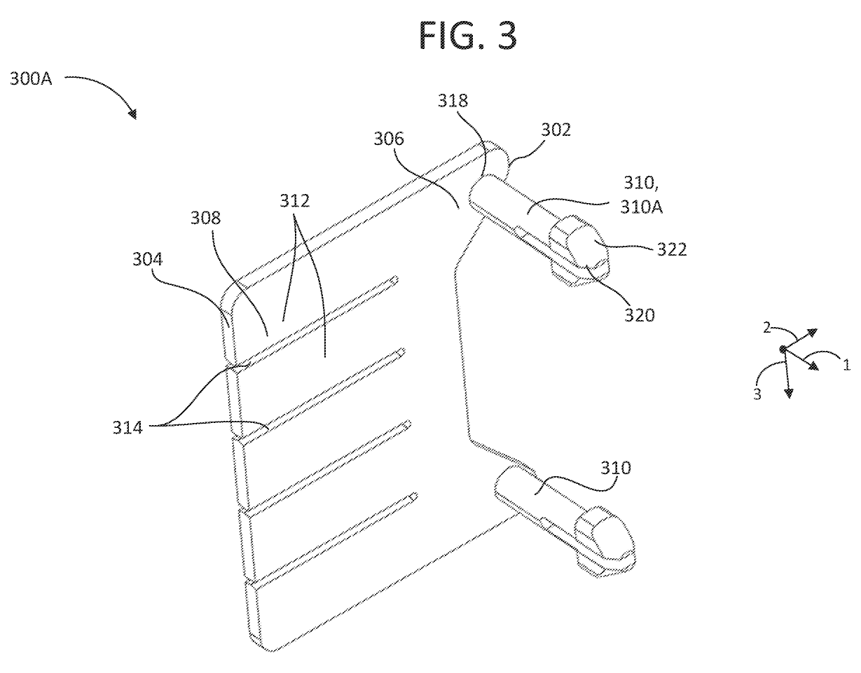

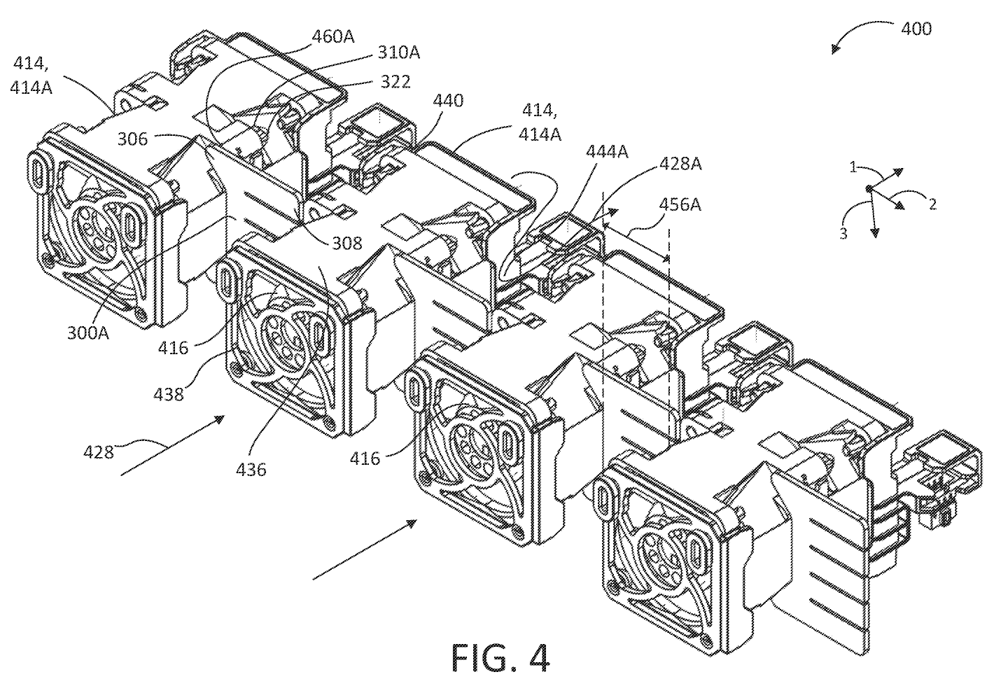

FIG. 3 depicts a perspective view of a first baffle 300A. In some examples, the first baffle 300A includes a fixed end 302, a free end 304, an attachment portion 306, and a finger portion 308. In some examples, the free end 304 is opposite to the fixed end 302. Further, the free end 304 is movable or bendable relative to the fixed end 302. The attachment portion 306 is located at the fixed end 302 and includes mechanical mounting members 310. In some examples, each of the mechanical mounting members 310 is a protrusion 310A extending along a first axis 1 and having a first end 318 attached to the attachment portion 306 and a second end 320 having an elastic catch 322 which may be configured to detachably couple with complementary mechanical mounting members 480 (as shown in FIG. 4) of the support structure 414 so as to releasably mount the first baffle 300A to an information processing device 400. The finger portion 308 is located at the free end 304 of the first baffle 300A and extending along a second axis 2. In some examples, the finger portion 308 includes a plurality of flaps 312, each extending from the attachment portion 306 to the free end 304. In particular, the plurality of flaps 312 is spaced apart from each other by a plurality of grooves 314 extending from the free end 304 towards the attachment portion 306. In some examples, each flap of the plurality of flaps 312 is independently movable so as to allow an obstructing electronic element (e.g., cable) of the information processing device 400 to pass from one area to another area of the information processing device 400 by extending the cable via a corresponding groove 314 of the finger portion 308. Similarly, in some other examples, each flap 312 may be independently bendable to allow the finger portion 308 to be disposed in a constrained space of the information processing device 400. Further, the finger portion 308 has a planar geometry along the second axis 2. In some examples, the finger portion 308 and the attachment portion 306 may include a compliant material such as a rubber material or a silicone material. In such examples, the first baffle 300A may be a unitary component. Further, in one or more examples, the compliant material may be a thermally non-conductive material.

FIG. 4 depicts a perspective view of a portion of an information processing device 400. In some examples, the portion of the information processing device 400 includes support structures 414, fans 416, and the first baffles 300A of FIG. 3. In some examples, the information processing device 400 may additionally include a chassis, a primary system board, processors, memory modules, power supply units, storage modules, or the like, which are not shown for ease of illustration of the essential components of the present disclosure.

Each support structure 414 is configured to house and/or provide support to fans 416. In some examples, the support structure 414 is a fan cage 414A. The fan cage 414A includes a plurality of fan housings 436 configured to support a corresponding fan 416 therein. Further each fan housing 436 has a first opening 438 and a second opening 440, opposite to the first opening 438. In such examples, each fan 416 is configured to draw fluid 428 into the fan housing 436 via the first opening 438 and direct the pumped fluid 428 out of the fan housing 436 via the second opening 440. In particular, the pumped fluid 428 is directed along a fluid flow path (not shown) defined along the processors, the DIMMS, the primary system board of the information processing device 400 so as to dissipate the heat generated from those components. Further, each fan housing 436 includes first complementary mechanical mounting members such as recesses 460A. Further, the fan cages 414A are disposed adjacent to each other and spaced apart from each other by a first width 456A along a second axis 2, thereby creating a first dead zone 444A along the fluid flow path.

Each first baffle 300A is disposed between two mutually adjacent fan cages 414A such that the attachment portion 306 contacts one fan cage 414A and the finger portion 308 extends along the second axis 2 and contacts a mutually adjacent fan cage 414A so as to laterally cover the first dead zone 444A along the second axis 2. Further, the protrusion 310A of the first baffle 300A extends into the recess 460A of the adjacent fan cage 414A and the elastic catch 322 of the protrusion 310A engages with the recesses 460A so as to detachably couple the first baffle 300A to the fan cage 414A. In such examples, a first portion 428A of the fluid 428 pumped from each fan 416 may be directed towards the first dead zone 444A. In such examples, the first baffle 300A disposed at the first dead zone 444A may not allow the first portion 428A of the fluid 428 to flow into first dead zone 444A and guide the first portion 428A of the fluid 428 back into the fluid flow path. In other words, the first baffle 300A may direct the first portion 428A of the fluid 428 moving towards the first dead zone 444A to flow along the fluid flow path.

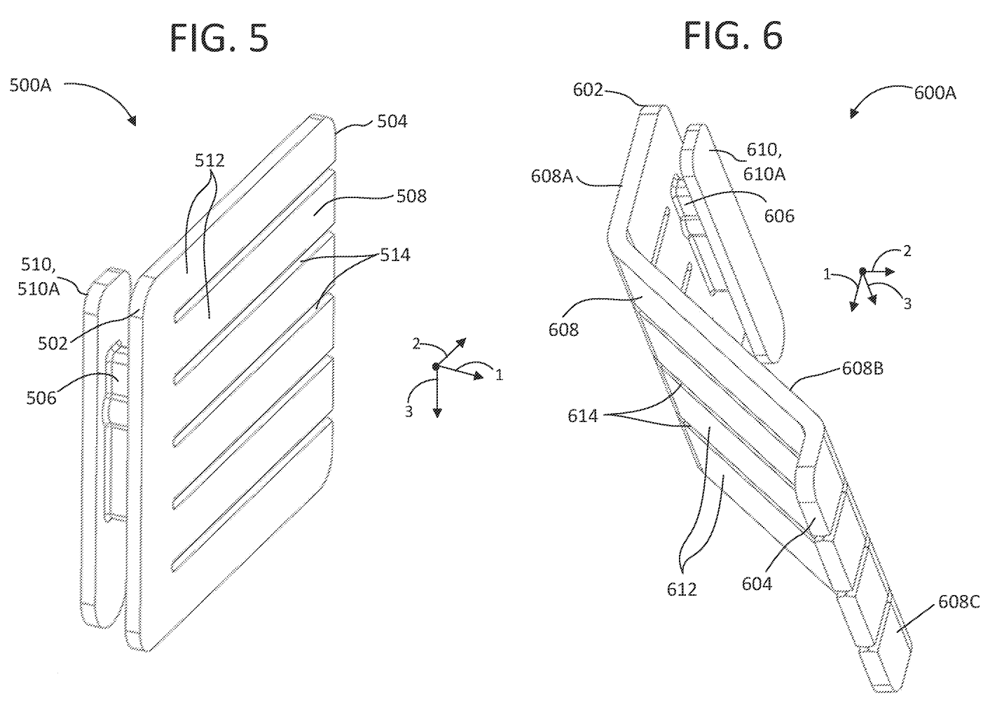

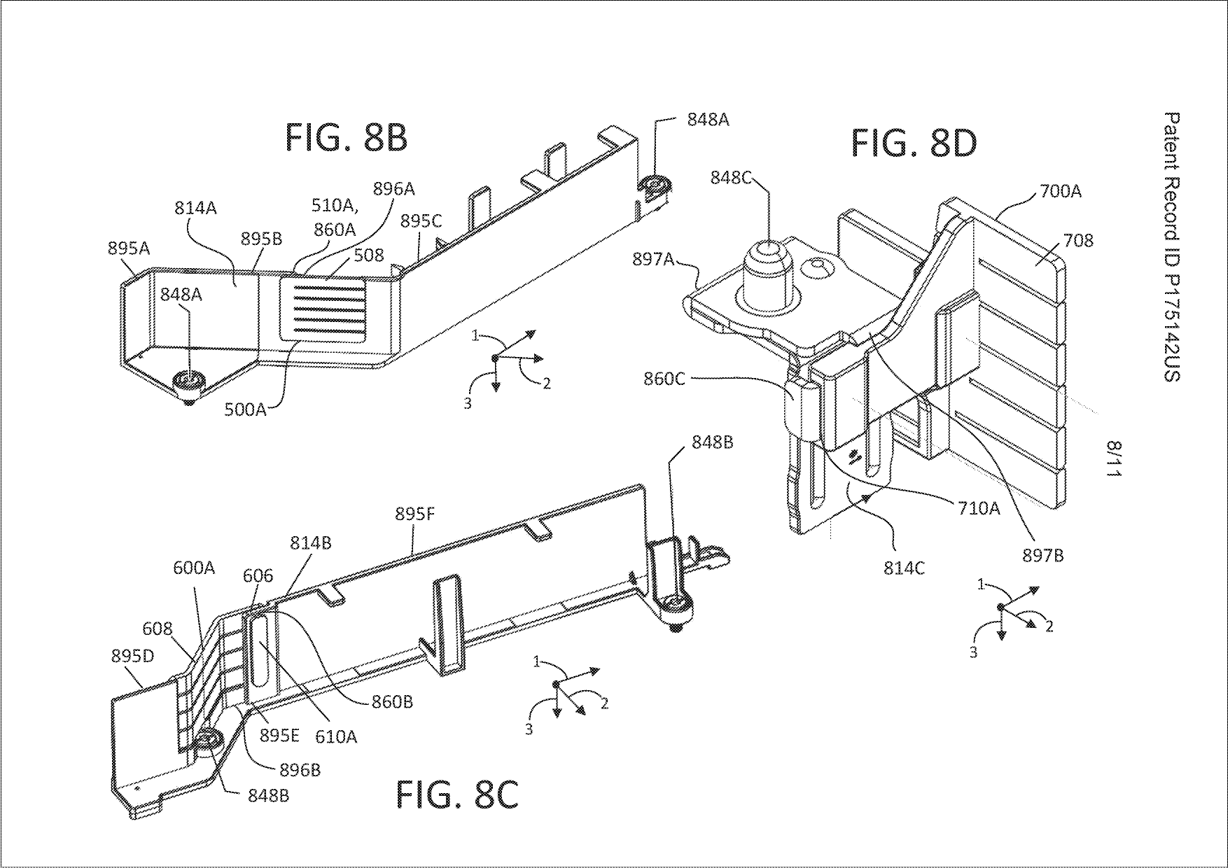

FIG. 5 depicts a perspective view of a second baffle 500A. In some examples, the second baffle 500A includes a fixed end 502, a free end 504, an attachment portion 506, and a finger portion 508. In some examples, the free end 504 is opposite to the fixed end 502. Further, the free end 504 is movable or bendable relative to the fixed end 502. The attachment portion 506 is located at the fixed end 502 and includes a mechanical mounting member 510 which may be configured to detachably couple with a complementary mechanical mounting member 880 (as shown in FIG. 8A) of the support structure 814 so as to releasably mount the second baffle 500A to an information processing device 800. In some examples, the mechanical mounting member 510 is a hook 510A. The finger portion 508 is located at the free end 504 of the second baffle 500A. In some examples, the finger portion 508 includes a plurality of flaps 512, each extending from the attachment portion 506 to the free end 504 along the second axis 2. In particular, the plurality of flaps 512 is spaced apart from each other by a plurality of grooves 514 extending from the free end 504 towards the attachment portion 506. In some examples, each flap of the plurality of flaps 512 is independently movable so as to allow an obstructing electronic element (e.g., cable) of the information processing device 800 to pass from one area to another area of the information processing device 800 by extending the cable via a corresponding groove 514 of the finger portion 508. Similarly, in some other examples, each flap 512 may be independently bendable to allow the finger portion 508 to be disposed in a constrained space of the information processing device 800. Further, the finger portion 508 has a planar geometry along the second axis 2. In some examples, the finger portion 508 and the attachment portion 506 may include a compliant material such as a rubber material or a silicone material. In such examples, the second baffle 500A may be a unitary component. Further, in one or more examples, the compliant material may be a thermally non-conductive material.

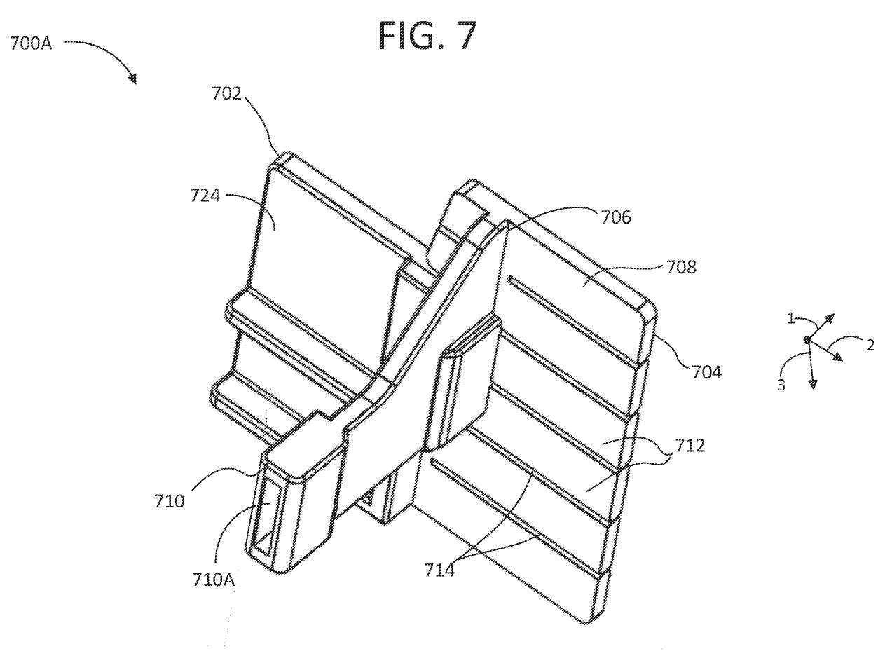

FIG. 6 depicts a perspective view of another second baffle 600A. In some examples, the other second baffle 600A includes a fixed end 602, a free end 604, an attachment portion 606, and a finger portion 608. In some examples, the free end 604 is opposite to the fixed end 602. Further, the free end 604 is movable or bendable relative to the fixed end 602. The attachment portion 606 is located at the fixed end 602 and includes a mechanical mounting member 610 which may be configured to detachably couple with a complementary mechanical mounting member 880 (as shown in FIG. 8A) of the support structure 814 so as to releasably mount the other second baffle 600A to an information processing device 800. In some examples, the mechanical mounting member 610 is a hook 610A. The finger portion 608 is located at the free end 604 of the other second baffle 600A. In some examples, the finger portion 608 includes a first section 608A, a second section 608B, and a third section 608C. The first section 608A extends along first axis 1 from the attachment portion 606, the second section 608B extends angularly from the first section 608A, and the third section 608C extends along the first axis 1 from the second section 608B. In some examples, the second section 608B may extend along 45 degrees relative to the first section 608A. In some examples, the finger portion 608 includes a plurality of flaps 612, each extending from the attachment portion 606 to the free end 604. In particular, the plurality of flaps 612 is spaced apart from each other by a plurality of grooves 614 extending from the free end 604 towards the attachment portion 606. In some examples, each flap of the plurality of flaps 612 is independently movable so as to allow an obstructing electronic element (e.g., cable) of the information processing device 800 to pass from one area to another area of the information processing device 800 by extending the cable via a corresponding groove 614 of the finger portion 608. Similarly, in some other examples, each flap 612 may be independently bendable to allow the finger portion 608 to be disposed in a constrained space of the information processing device 800. Further, the finger portion 608 has an angular geometry as discussed hereinabove. In some examples, the finger portion 608 and the attachment portion 606 may include a compliant material such as a rubber material or a silicone material. In such examples, the other second baffle 600A may be a unitary component. Further, in one or more examples, the compliant material may be a thermally non-conductive material.

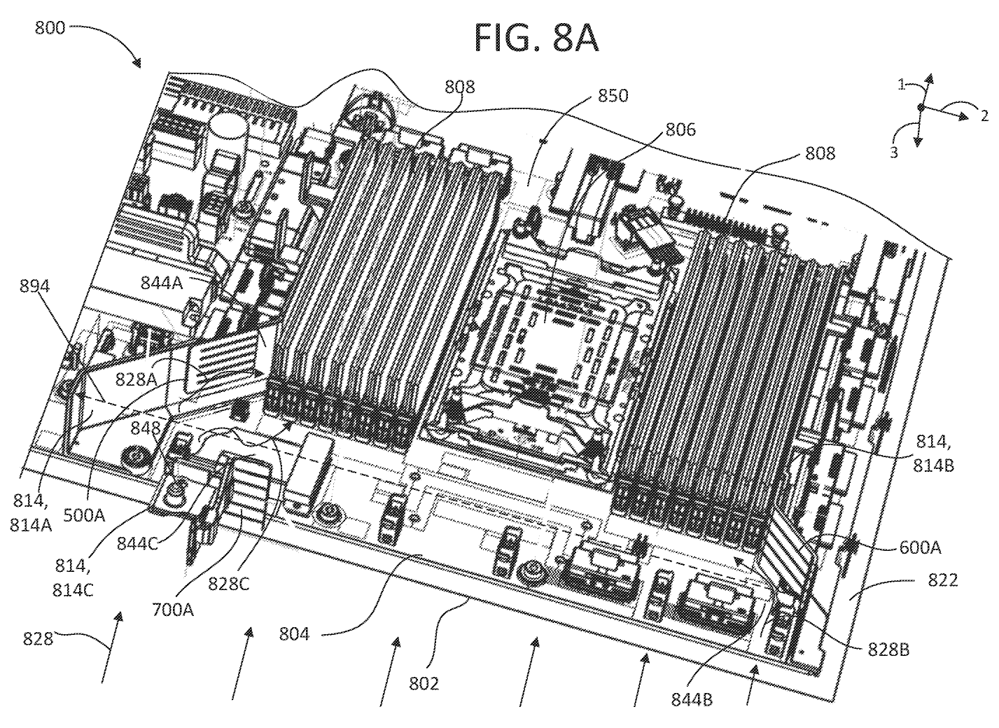

FIG. 7 depicts a perspective view of a third baffle 700A. In some examples, the third baffle 700A includes a fixed end 702, a free end 704, an attachment portion 706, and a finger portion 708. In some examples, the free end 704 is opposite to the fixed end 702. Further, the free end 704 is movable or bendable relative to the fixed end 702. The attachment portion 706 is located adjacent to the fixed end 702 and includes a mechanical mounting member 710. In some examples, the mechanical mounting member 710 includes a groove 710A which may be configured to detachably couple with a complementary mechanical mounting member 880 (as shown in FIG. 8A) of the support structure 814 so as to releasably mount the third baffle 700A to an information processing device 800. In some examples, the mechanical mounting member 710 extends perpendicularly from the attachment portion 706 along a first axis 1. The finger portion 708 is located at the free end 704 of the third baffle 700A and extends along a second axis 2. In some examples, the finger portion 708 has a planar geometry along the second axis 2. In some examples, the finger portion 708 includes a plurality of flaps 712, each extending from the attachment portion 706 to the free end 704. In particular, the plurality of flaps 712 is spaced apart from each other by a plurality of grooves 714 extending from the free end 704 towards the attachment portion 706. In some examples, each flap of the plurality of flaps 712 is independently movable so as to allow an obstructing electronic element (e.g., cable) of the information processing device 800 to pass from one area to another area of the information processing device 800 by extending the cable via a corresponding groove 714 of the finger portion 708. Similarly, in some other examples, each flap 712 may be independently bendable to allow the finger portion 708 to be disposed in a constrained space of the information processing device 800. Further, the third baffle 700A includes a second finger portion 724 extending from the finger portion 708 in an opposite direction to that of the finger portion 708. The second finger portion 724 has a planar geometry and may not include plurality of flaps as that is available in the finger portion 708. In some examples, the finger portion 708, the second finger portion 724, and the attachment portion 706 may include a compliant material such as a rubber material or a silicone material. In such examples, the third baffle 700A may be a unitary component. Further, in one or more examples, the compliant material may be a thermally non-conductive material.

FIG. 8A depicts a perspective view of a portion of another information processing device 800 having the second baffles 500A, 600A of FIGS. 5-6 and a third baffle 700A of FIG. 7. FIG. 8B depicts an expanded perspective view of the second baffle 500A detachably coupled to a memory support member 814A-1 of the information processing device 800 of FIG. 8A. FIG. 8B depicts an expanded perspective view of the other second baffle 600A detachably coupled to another memory support member 814A-2 of the information processing device 800 of FIG. 8A. FIG. 8C depicts an expanded perspective view of the third baffle 700A detachably coupled to a top cover holder 714A of the information processing device 800 of FIG. 8A. In the description hereinafter, FIGS. 8A-8D are described concurrently for ease of illustration. The information processing device 800 further includes a chassis 802, a primary system board 804, a processor 806, memory modules 808, and support structures 814. It may be noted herein that fans of the information processing device 800 are not depicted herein for ease of illustration.

The chassis 802 includes panels a base 822 configured to support the components such as the primary system board 804, the support structures 814, or the like. The processor 806 and the memory modules 808 are mounted thereon the primary system board 804. In some examples, the support structures 814 include a memory support member 814A, another memory support member 814B, and a top cover holder 814C. The memory support member 814A and the other memory support member 814B are disposed spaced apart from each other by a distance 894 such that the components such as the processor 806 and the memory modules 808 are disposed therein. The top cover holder 814C is disposed at adjacent to a front end (not labeled) of the memory support member 814A.

The memory support member 814A includes a first section 895A, a second section 895B, and a third section 895C sequentially connected to one another. In such examples, the second section 895B includes an opening 896A having a shape that is substantially complimentary to that of the second baffle 500A. In some examples, the first and third sections 895A, 895C extends along a first axis 1 and the second section 895B extends angularly from the first and third sections 895A, 895C, thereby creating a first dead zone 844A along the fluid flow path 850. Further, the second section 895B includes a second complementary mechanical mounting member such as a keyhole 860A adjacent to the opening 896A. In such examples, the second baffle 500A is disposed on the second section 895B of the memory support member 814A such that the finger portion 508 extends angularly and contacts the first and third sections 895A, 895C and angularly cover the first dead zone 844A and the hook 810A of the second baffle 500A is engaged with the keyhole 860A of the memory support member 814A so as to detachably couple the second baffle 500A to the memory support member 814A. The second baffle 500A has a planar geometry and is configured to restrain a flow of a first portion 828A of a fluid 828 to a fluid flow path 850 defined in the information processing device 800. The first and third sections are coupled to the base 822 via a corresponding fastener 848A.

The other memory support member 814B includes a first section 895D, a second section 895E, and a third section 895F sequentially connected to one another. In such examples, the second section 895E includes a second opening 896D having a shape that is substantially complimentary to that of the other second baffle 600A. In some examples, the first and third sections 895D, 895F extend along a first axis 1 and the second section 895E extends angularly from the first and the third sections 895D, 895F, thereby creating a second dead zone 844B along the fluid flow path 850. Further, the second section 895E includes a second complementary mechanical mounting member such as a keyhole 860B adjacent to the second opening 896B. In such examples, the other second baffle 600A is disposed on the second section 895E of the other memory support member 814B such that the finger portion 608 extends angularly and contacts first and third sections 895D, 895F and angularly cover the second dead zone 844B and the hook 810B of the other second baffle 600A is engaged with the keyhole 860B of the other memory support member 814B so as to detachably couple the other second baffle 600A to the other memory support member 814B. The other second baffle 600A has a planar geometry and is configured to restrain the flow of a second portion 828B of the fluid 828 to the fluid flow path 850 defined in the information processing device 800. The first and third sections 895D, 895F are coupled to the base 822 via a corresponding second fastener 848B.

The top cover holder 814C may be disposed between two adjacent fan housings of a fan cage such that one end wall 897A of the top cover holder 814C is coupled to one sidewall of a fan housing. However, another end wall 897B of the top cover holder 814C may be disposed spaced apart from the adjacent fan housing, and thereby creating a third dead zone 844C along the fluid flow path 850. The top cover holder 814C further includes a pin 848 extending upwards along a third axis 3 and configured to engage with a recess of a cover (not shown) of the information processing device 800 to detachably couple and provide support to the cover. Further, the top cover holder 814C may include a third complementary mechanical mounting members such as a hook 860C configured to engage with the third mechanical mounting members 710C of the third baffle 700C so as to detachably couple the third baffle 700C to the top cover holder 814C. In such examples, the third baffle 700A is disposed adjacent to the other end wall 897B of the top cover holder 814C such that the finger portion 708 of the third baffle 700A laterally covers the third dead zone 844C along the second axis 2 and the hook 860C of the top cover holder 814C is engaged with the groove 710A of the third baffle 700A so as to detachably couple the third baffle 700A to the top cover holder 814C. The third baffle 700A has a planar geometry and is configured to restrain the flow of third portion 828C of the fluid 828 to the fluid flow path 850 defined in the information processing device 800.

During operation of the information processing device 800, the fans may draw and direct the fluid 828 to the fluid flow path 850. However, a first portion 828A of the pumped fluid 828 may be directed towards the first dead zone 844A. In such examples, the second baffle 500A disposed at the first dead zone 844A may not allow the first portion 828A of the fluid 828 to flow into first dead zone 844A and guide the first portion 828A of the fluid 828 back into the fluid flow path 850. Similarly, a second portion 828B of the pumped fluid 828 may be directed towards the second dead zone 844B. In such examples, the other second baffle 600B disposed at the second dead zone 844B may not allow the second portion 828B of the fluid 828 to flow into the second dead zone 844B and guide the second portion 828B of the fluid 828 back into the fluid flow path 850. Furthermore, a third portion 828C of the pumped fluid 828 may be directed towards the third dead zone 844C. In such examples, the third baffle 700A disposed at the third dead zone 844C may not allow a third portion 828C of the fluid 828 to flow into third dead zone 844C and guide the third portion 828C of the fluid 828 back into the fluid flow path 850. The fluid 828 flowing in the fluid flow path 850 may flow over the electronic components such as the processors 806, memory modules 808, and primary system board 804, and later dissipate the heat away from such electronic components before exiting from the information processing device 800.

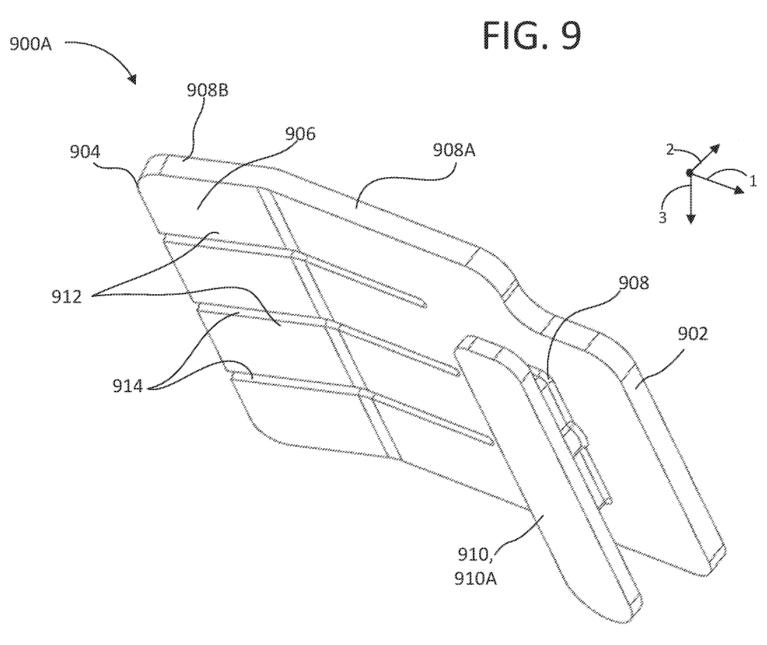

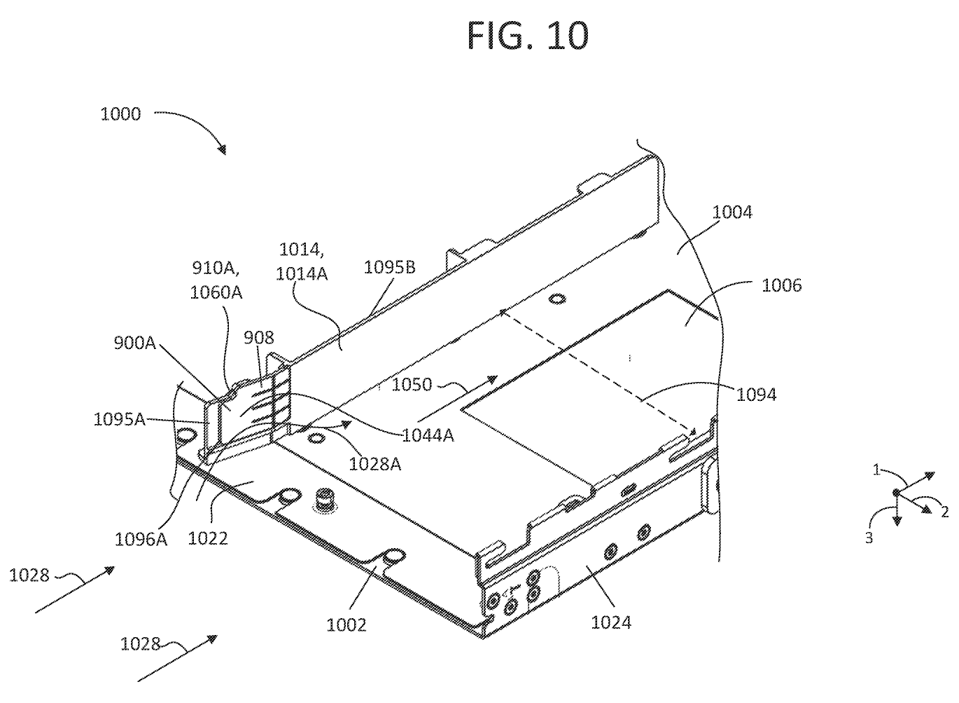

FIG. 9 depicts a perspective view of yet another second baffle 900A. In some examples, the other second baffle 900A includes a fixed end 902, a free end 904, an attachment portion 906, and a finger portion 908. In some examples, the free end 904 is opposite to the fixed end 902. Further, the free end 904 is movable or bendable relative to the fixed end 902. The attachment portion 906 is located at the fixed end 902 and includes a mechanical mounting member 910 which may be configured to detachably couple with a complementary mechanical mounting member 1080 (as shown in FIG. 10) of the support structure 1014 so as to releasably mount the other second baffle 900A to an information processing device 1000. In some examples, the mechanical mounting member 910 is a hook 910A. The finger portion 908 is located at the free end 904 of the other second baffle 900A. In some examples, the finger portion 908 includes a first section 908A and a second section 908B connected to each other. The first section 908A extends along first axis 1 from the attachment portion 906 and the second section 908B extends angularly from the first section 908A. In some examples, the second section 908B may extend along 15 degrees relative to the first section 908A. In some examples, the finger portion 908 includes a plurality of flaps 912, each extending from the attachment portion 906 to the free end 904. In particular, the plurality of flaps 912 is spaced apart from each other by a plurality of grooves 914 extending from the free end 904 towards the attachment portion 906. In some examples, each flap of the plurality of flaps 912 is independently movable so as to allow an obstructing electronic element (e.g., cable) of the information processing device 1000 to pass from one area to another area of the information processing device 1000 by extending the cable via a corresponding groove 914 of the finger portion 908. Similarly, in some other examples, each flap 912 may be independently bendable to allow the finger portion 908 to be disposed in a constrained space of the information processing device 1000. Further, the finger portion 908 has the planar and angular geometry as discussed hereinabove. In some examples, the finger portion 908 and the attachment portion 906 may include a compliant material such as a rubber material or a silicone material. In such examples, the other second baffle 900A may be a unitary component. Further, in one or more examples, the compliant material may be a thermally non-conductive material.

FIG. 10 depicts a perspective view of a portion of another information processing device 1000 having the other second baffles 900A of FIG. 9. The information processing device 1000 further includes a chassis 1002 having a peripheral sidewall 1024, a primary system board 1004, a processor 1006, memory modules (not shown), and a support structure 1014. It may be noted herein that fans of the information processing device 1000 are not depicted herein for ease of illustration.

The chassis 1002 includes panels a base 1022 configured to support the components such as the primary system board 1004, the support structures 1014, or the like. The processor 1006 and the memory modules 1008 are mounted there on the primary system board 1004. In some examples, the support structure 1014 includes a memory support member 1014A. The memory support member 1014A is disposed spaced apart from the peripheral sidewall 1024 by a distance 1094 such that the components such as the processor 1006 and the memory modules 1008 are disposed therein.

The memory support member 1014A includes a first section 1095A and a second section 1095B connected to one another. In such examples, the first section 1095A includes an opening 1096A having a shape that is substantially complimentary to that of the other second baffle 900A. In some examples, the second section 1095B extends along a first axis 1 and the first section 1095A extends angularly from the second section 1095B, thereby creating a dead zone 1044A along the fluid flow path 1050. Further, the first section 1095A includes a second complementary mechanical mounting member such as a keyhole 1060A adjacent to the opening 1096A. In such examples, the other second baffle 900A is disposed on the first section 1095A of the memory support member 1014A such that the finger portion 908 extends angularly and contacts the second section 1095B and angularly cover the dead zone 1044A and the hook 910A of the other second baffle 900A is engaged with the keyhole 1060A of the memory support member 1014A so as to detachably couple the other second baffle 900A to the memory support member 1014A. The other second baffle 900A has a planar and angular geometry and is configured to restrain a flow of a portion 1028A of a fluid 1028 to the fluid flow path 1050 defined in the information processing device 1000. The first and second sections 1095A, 1095B are coupled to the base 1022 via a corresponding fastener.

During operation of the information processing device 1000, the fans may draw and direct the fluid 1028 to the fluid flow path 1050. However, a portion 1028A of the pumped fluid 1028 may be directed towards the dead zone 1044A. In such examples, the other second baffle 900A disposed at the dead zone 1044A may not allow the portion 1028A of the fluid 1028 to flow into the dead zone 1044A and guide the portion 1028A of the fluid 1028 back into the fluid flow path 1050. The fluid 1028 flowing in the fluid flow path 1050 may flow over the electronic components such as the processors 1006, DIMMs, and primary system board 1004, and later dissipate the heat away from such electronic components before exiting from the information processing device 1000.

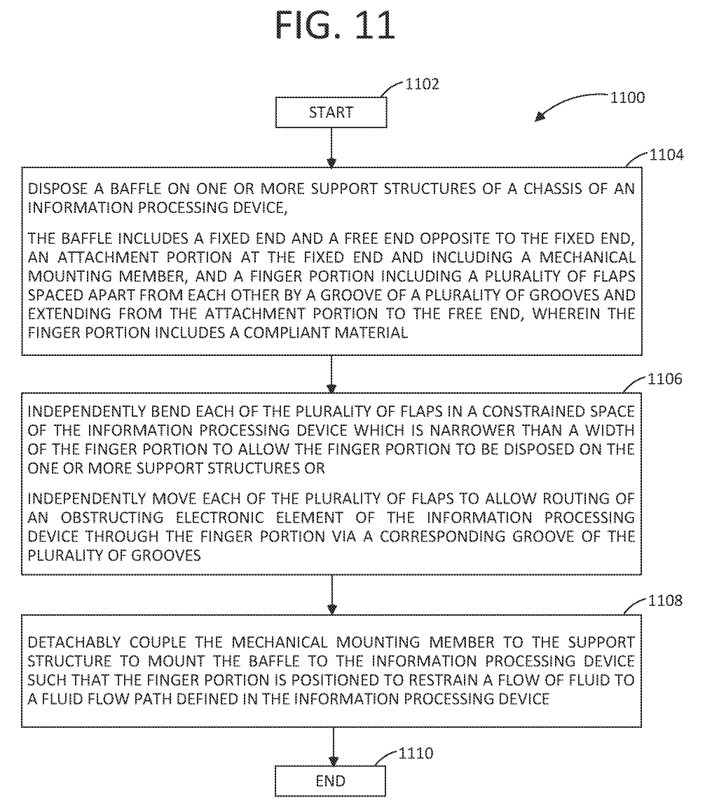

FIG. 11 includes a flowchart showing a method 1100 of installing a baffle in an information processing device. It may be noted herein that the method 1100 is described in conjunction with FIGS. 1-2, for example. The method 1100 starts at block 1102 and continues to block 1104.

At block 1104, the method 1100 includes disposing a baffle on one or more support structures of a chassis of an information processing device. In some examples, the baffle includes a fixed end and a free end opposite to the fixed end, an attachment portion at the fixed end and including a mechanical mounting member, and a finger portion including a plurality of flaps spaced apart from each other by a groove of a plurality of grooves and extending from the attachment portion to the free end, wherein the finger portion includes a compliant material. The method 1100 continues to block 1106.

At block 1106, the method 1100 includes independently bending each of the plurality of flaps in a constrained space of the information processing device which is narrower than a width of the finger portion to allow the finger portion to be disposed on the one or more support structures or independently moving each of the plurality of flaps to allow routing of an obstructing electronic element of the information processing device through the finger portion via a corresponding groove of the plurality of grooves. The method 1100 continues to block 1108.

At block 1108, the method 1100 includes detachably coupling the mechanical mounting member to the support structure to releasably mount the baffle to the information processing device such that the finger portion is positioned to restrain a flow of fluid to a fluid flow path defined in the information processing device. In some examples, the one or more support structures of the information processing device comprise a fan cage, a top cover holder, or a memory module support member. Furthermore, the compliant material is a rubber material or a silicon material. The method 1100 ends at block 1110.

In the foregoing description, numerous details are set forth to provide an understanding of the subject matter disclosed herein. However, implementation may be practiced without some or all of these details. Other implementations may include modifications, combinations, and variations from the details discussed above. It is intended that the following claims cover such modifications and variations.

What is claimed is:

1. A baffle for an information processing device, comprising:
a fixed end and a free end opposite to the fixed end;
an attachment portion at the fixed end and comprising a mechanical mounting member, wherein the mechanical mounting member is configured to detachably couple to a support structure of the information processing device so as to mount the attachment portion to the information processing device; and
a finger portion comprising a plurality of flaps extending from the attachment portion to the free end and configured to restrain a flow of fluid to a fluid flow path defined in the information processing device, wherein the finger portion comprises a compliant material.

2. The baffle of claim 1, wherein the plurality of flaps is spaced apart from each other by a groove of a plurality of grooves extending from the free end towards the attachment portion.

3. The baffle of claim 2, wherein each flap of the plurality of flaps is independently movable to allow an obstructing electronic element of the information processing device to pass through the finger portion via a corresponding groove of the plurality of grooves and independently bendable to allow the finger portion to be disposed in a constrained space of the information processing device which is narrower than a width of the finger portion.

4. The baffle of claim 1, is a unitary component comprising the compliant material.

5. The baffle of claim 1, wherein the compliant material is a thermally non-conductive material.

6. The baffle of claim 1, wherein the compliant material is one of a rubber material or a silicon material.

7. The baffle of claim 1, wherein the mechanical mounting member comprises one of a protrusion, a hook, or a groove.

8. The baffle of claim 1, wherein the finger portion comprises one of a planar geometry or an angular geometry.

9. An information processing device comprising:
a chassis;
a primary system board disposed in the chassis and comprising a plurality of electronic components;
a fluid flow path defined along the plurality of electronic components;
a support structure installed in the chassis; and
a baffle disposed in the chassis, comprising:
a fixed end and a free end opposite to the fixed end;
an attachment portion at the fixed end and comprising a mechanical mounting member, wherein the mechanical mounting member is detachably coupled to the support structure to mount the attachment portion to the chassis; and
a finger portion comprising a plurality of flaps extending from the attachment portion to the free end and configured to restrain a flow of fluid to the fluid flow path, wherein the finger portion comprises a compliant material.

10. The information processing device of claim 9, wherein the plurality of flaps is spaced apart from each other by a groove of a plurality of grooves extending from the free end towards the attachment portion.

11. The information processing device of claim 10, wherein each flap of the plurality of flaps is independently movable to allow an obstructing electronic element of the information processing device to pass through the finger portion via a corresponding groove of the plurality of grooves and independently bendable to allow the finger portion to be disposed in a constrained space of the information processing device which is narrower than a width of the finger portion.

12. The information processing device of claim 9, is a unitary component comprising the compliant material.

13. The information processing device of claim 9, wherein the compliant material is a thermally non-conductive material.

14. The information processing device of claim 9, wherein the compliant material is one of a rubber material or a silicon material.

15. The information processing device of claim 9, wherein the support structure is a fan cage comprising a recess, wherein the finger portion comprises a planar geometry, wherein the mechanical mounting member comprises a protrusion including an elastic catch, and wherein the elastic catch is detachably coupled to the recess to releasably mount the baffle to the fan cage.

16. The information processing device of claim 9, wherein the support structure is a top cover holder of the chassis, comprising a hook, wherein the finger portion comprises a planar geometry, wherein the mechanical mounting member comprises a groove, and wherein the groove is detachably coupled to the hook to releasably mount the baffle to the top cover holder.

17. The information processing device of claim 9, wherein the support structure is a memory support member of the chassis, comprising a keyhole, wherein the finger portion comprises one of a planar geometry or an angular geometry, wherein the mechanical mounting member comprises a hook, and wherein the hook is detachably coupled to the keyhole to releasably mount the baffle to the memory support member.

18. A method comprising:
disposing a baffle on one or more support structures of a chassis of an information processing device, wherein the baffle comprises:
a fixed end and a free end opposite to the fixed end;
an attachment portion at the fixed end and comprising a mechanical mounting member; and
a finger portion comprising a plurality of flaps spaced apart from each other by a groove of a plurality of grooves and extending from the attachment portion to the free end, wherein the finger portion comprises a compliant material;
independently bending each of the plurality of flaps in a constrained space of the information processing device which is narrower than a width of the finger portion to allow the finger portion to be disposed on the one or more support structures or independently moving each of the plurality of flaps to allow routing of an obstructing electronic element of the information processing device through the finger portion via a corresponding groove of the plurality of grooves; and
detachably coupling the mechanical mounting member to the support structure to mount the baffle to the information processing device such that the finger portion is positioned to restrain a flow of fluid to a fluid flow path defined in the information processing device.

19. The method of claim 18, wherein the one or more support structures of the information processing device comprise a fan cage, a top cover holder, or a memory support member.

20. The method of claim 18, wherein the compliant material is one of a rubber material or a silicon material.
